(19) United States
(12) Patent Application Publication
(10) Pub. No.: US 2026/0136865 A1
(43) Pub. Date: May 14, 2026

(54) MULTI-COMPARTMENT GAS PANEL ASSEMBLY

(71) Applicant: Applied Materials, Inc., Santa Clara, CA (US)

(72) Inventors: Skanda Simha Chandrashekar, Bengaluru (IN); Chakrapani Rayan Thimmaiah, Bengaluru (IN); Mahadev Joshi, Bengaluru (IN)

(73) Assignee: Applied Materials, Inc., Santa Clara, CA (US)

(21) Appl. No.: 18/947,268

(22) Filed: Nov. 14, 2024

(51) Int. Cl. H01L 21/67

(52) U.S. Cl. CPC H10P 72/0402

(57) ABSTRACT

Disclosed herein is a gas panel assembly operable with a substrate processing chamber, the gas panel assembly including an enclosure defining a first compartment and a second compartment separated by a divider wall. A first gas pallet assembly within the first compartment is operable to provide a first gas to the substrate processing chamber, and a second gas pallet assembly within the second compartment is operable to provide a second gas to the substrate processing chamber. The gas panel assembly may further include a first flow control device between the first compartment and an exhaust, the first flow control device operable to control air flow between the first compartment and the exhaust, and a duct connecting the second compartment and the exhaust, wherein a second flow control device is operable to control air flow between the second compartment and the duct.

### FIELD OF THE DISCLOSURE

The present disclosure relates to gas panel assemblies for semiconductor processing systems and, in particular, to a gas panel assembly including a plurality of compartments connected to a same exhaust.

### BACKGROUND OF THE DISCLOSURE

Semiconductor processing utilizes inert, toxic, corrosive, and flammable gases, which require the use of various operative air flow control and air filtering devices to ensure that the desired quantity of contaminant free gas reaches a semiconductor process chamber. The operative air flow control and filtering devices are typically assembled in linear clusters of interconnected elements forming individual gas specific flow control channels, which are sometimes referred to as “gas sticks.” The gas sticks are often mounted to a common manifold, with the entire distribution assembly then mounted to a pallet of a gas panel for handling and maintenance purpose.

Current gas panel designs suffer from elevated exhaust flow rates, bulkiness, considerable weight, high cost, and a lack of individual compartments for each process chamber's specific requirements. Furthermore, when one area of the gas panel is under service or maintenance, the entire gas panel enclosure, along with its corresponding processing chamber, must be shut down. This leads to a decrease in productivity, lower throughput, and increased system downtime. Current gas panel designs also result in a low air exchange rate and a lack of eco-efficiency in the gas panel. Additionally, the enclosure has a limited gas stick capacity.

There remains a need in the art for an improved gas panel assembly design.

### Summary

This Summary is provided to introduce a selection of concepts in a simplified form that are further described below in the Detailed Description. This Summary is not intended to identify key features or essential features of the claimed subject matter, nor is it intended as an aid in determining the scope of the claimed subject matter.

In one aspect, a gas panel assembly may include an enclosure defining a first compartment and a second compartment separated from one another by a divider wall, and a first gas pallet assembly within the first compartment, wherein the first gas pallet assembly is operable to provide a first gas to a first substrate processing chamber. The gas panel assembly may further include a second gas pallet assembly within the second compartment, wherein the second gas pallet assembly is operable to provide a second gas to a second substrate processing chamber. The gas panel assembly may further include a first flow control device between the first compartment and an exhaust, the first flow control device operable to control air flow between the first compartment and the exhaust. The gas panel assembly may further include a duct connecting the second compartment and the exhaust, wherein a second flow control device is operable to control air flow between the second compartment and the duct.

In another aspect, a gas panel assembly of a semiconductor processing system may include an enclosure comprising a top plate opposite a bottom plate, a first side plate opposite a second side plate, and a divider wall extending between the first and second side plates, wherein the divider wall separates a first compartment from a second compartment. The gas panel assembly may further include a first gas pallet assembly and a first plurality of electrical components within the first compartment, wherein the first plurality of electrical components is operable to control gas flow from the first gas pallet assembly to a first substrate processing chamber. The gas panel assembly may further include a second gas pallet assembly and a second plurality of electrical components within the second compartment, wherein the second plurality of electrical components is operable to control gas flow from the second gas pallet assembly to a second substrate processing chamber. The gas panel assembly may further include a first flow control device coupled to the top plate, the first flow control device operable to control air flow between the first compartment and an exhaust, and a duct extending between the second compartment and the exhaust. A second flow control device coupled to the divider wall is operable to control air flow of between the second compartment and the duct, wherein the duct extends through an interior of the first compartment.

In yet another aspect, an apparatus for delivering gases to one or more substrate processing chamber may include an enclosure comprising a top plate opposite a bottom plate, a first side plate opposite a second side plate, and a divider wall extending between the first and second side plates, wherein the divider wall separates a first compartment from a second compartment. The apparatus may further include a first gas pallet assembly and a first plurality of electrical components within the first compartment, wherein the first plurality of electrical components is operable to control gas flow from the first gas pallet assembly to a first substrate processing chamber. The apparatus may further include a second gas pallet assembly and a second plurality of electrical components within the second compartment, wherein the second plurality of electrical components is operable to control gas flow from the second gas pallet assembly to a second substrate processing chamber. The apparatus may further include a first flow control device coupled to the top plate, the first flow control device operable to control air flow between the first compartment and an exhaust, and a duct connecting the second compartment and the exhaust, wherein a second flow control device coupled to the divider wall is operable to control air flow between the second compartment and the duct.

### Brief Description of the Drawings

The accompanying drawings illustrate exemplary approaches of the disclosure, including the practical application of the principles thereof, as follows:

FIG. 1 illustrates a perspective view of an example gas panel assembly, according to embodiments of the present disclosure;

FIG. 2 illustrates a side view of an example gas panel assembly, according to embodiments of the present disclosure;

FIG. 3A illustrates a side view of a first flow control device of a gas panel assembly, according to embodiments of the present disclosure;

FIG. 3B illustrates a side view of the first flow control device of the gas panel assembly, according to embodiments of the present disclosure;

FIG. 4A illustrates a perspective view of an exhaust and a second flow control device of a gas panel assembly, according to embodiments of the present disclosure; and

FIG. 4B illustrates an exploded perspective view of the exhaust and the second flow control device of the gas panel assembly, according to embodiments of the present disclosure.

The drawings are not necessarily to scale. The drawings are merely representations, not intended to portray specific parameters of the disclosure. The drawings are intended to depict exemplary embodiments of the disclosure, and therefore are not to be considered as limiting in scope. In the drawings, like numbering represents like elements.

Furthermore, certain elements in some of the figures may be omitted, or illustrated not-to-scale, for illustrative clarity. The cross-sectional views may be in the form of "slices", or "near-sighted" cross-sectional views, omitting certain background lines otherwise visible in a "true" cross-sectional view, for illustrative clarity. Furthermore, for clarity, some reference numbers may be omitted in certain drawings.

### Detailed Description

Apparatuses, systems, and devices in accordance with the present disclosure will now be described more fully hereinafter with reference to the accompanying drawings, where various embodiments are shown. The apparatuses, systems, and devices may be embodied in many different forms and are not to be construed as being limited to the embodiments set forth herein. Instead, these apparatuses, systems, and devices are provided so the disclosure will be thorough and complete, and will fully convey the scope of the apparatuses, systems, and devices to those skilled in the art.

To address the deficiencies of the prior art described above, disclosed herein is a gas panel assembly operable with one or more semiconductor process chambers, wherein the gas panel assembly includes an enclosure defining multiple compartments connected to a same exhaust. Operation of a first compartment may be arrested, for example, during maintenance, while a second compartment may continue to operate without interruption. To accomplish this, the first and second compartments may be separated by a divider wall, and series of flow control devices (e.g., blast gates) may be opened/closed to selectively control exhaust flow within the first and second compartments. More specifically, a first blast gate may be coupled to a top plate of the enclosure, and a second blast gate may be coupled to the divider wall. In some embodiments, an air duct extends between the exhaust and the divider wall to provide a path for the air in the second compartment to be released via the exhaust.

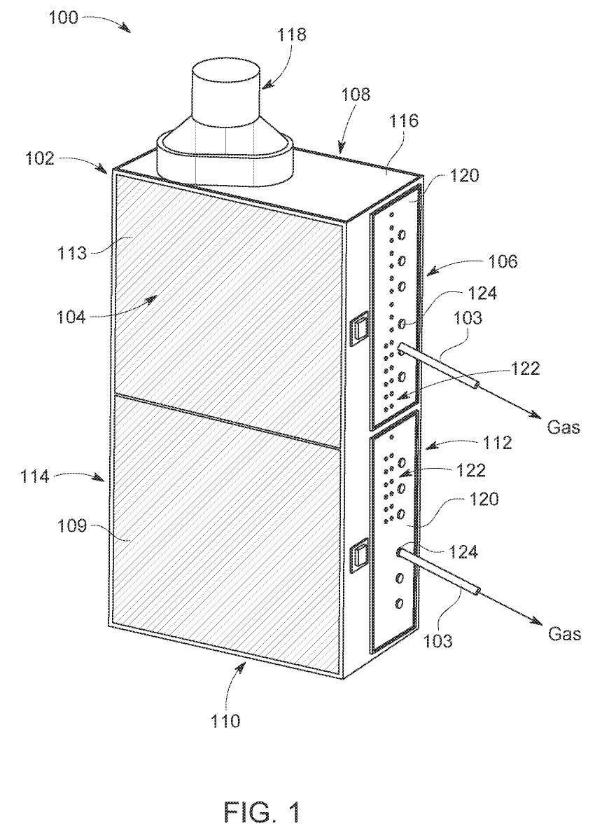

FIG. 1 illustrates an example gas panel assembly 100 according to embodiments of the disclosure. The gas panel assembly 100 may include a housing or enclosure 102, which is coupled to, or positioned adjacent to, a semiconductor processing system (not shown). The gas panel assembly 100 may be used for the delivery of various gases to one or more processing chambers via a plurality of gas ducts 103, the gases including flammable and toxic gases used during manufacture of semiconductor devices. Although non-limiting, the processing chambers may be one or more of an etch chamber (e.g., a plasma etch chamber), a deposition chamber (including atomic layer deposition (ALD), chemical vapor deposition (CVD), physical vapor deposition (PVD), or plasma enhanced versions thereof), anneal chamber, or the like. Although only a single gas panel assembly 100 is shown, multiple gas panels may be connected with the semiconductor processing system in alternative embodiments.

The enclosure 102 may include a plurality of perimeter walls defining a first main side 104 opposite a second main side 106, a first end 108 opposite a second end 110, and a first side 112 opposite a second side 114. The perimeter walls of the enclosure 102 assist in sealing the enclosure 102 to maintain a sub-atmospheric pressure therein.

The first main side 104 may include a first access panel 113 operable to provide access to a first compartment of the enclosure 102, and a second access panel 109 operable to provide access to a second compartment of the enclosure. As will be described in greater detail herein, the first and second compartments may be separated by a divider wall. The first end 108 may include a top plate 116, and an exhaust assembly 118 extending from the top plate 116.

The first side 112 and/or the second side 114 may include one or more side plates 120 each including a first plurality of openings 122 to receive ambient air into the enclosure 102 and one or more gas ports 124 for delivering gases from the enclosure 102 to multiple substrate processing chambers (not shown). As demonstrated, the gas ducts 103 may connect with the gas ports 124, which are connected with one or more gas sticks within the enclosure 102.

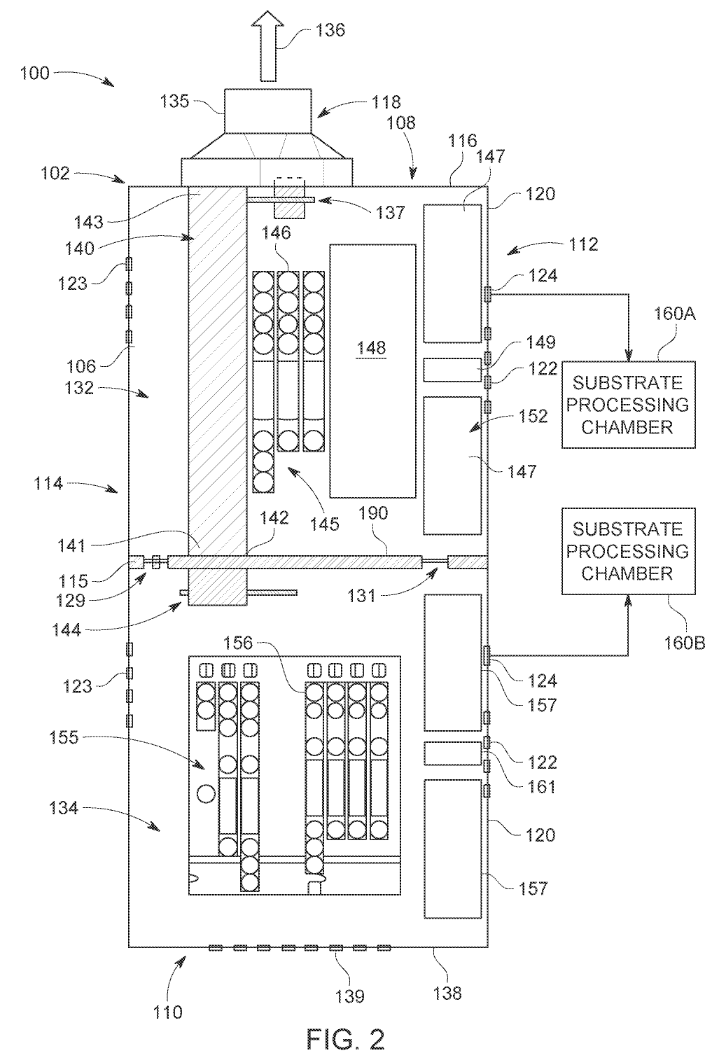

FIG. 2 is a side view of the gas panel assembly 100 with the first and second access panels 113, 109 removed for ease of viewing. The enclosure 102 may define a first compartment 132 and a second compartment 134 separated from one another by divider wall 115. As shown, the divider wall 115 may be plate, which extends between the first side 112 and the second side 114, the divider wall 115 creating a seal between the first and second compartments 132, 134. In some embodiments, the divider wall 115 may include a vacuum coupling radius (VCR) bulkhead 129 to connect common single line drop (SLD) lines between the first compartment 132 and the second compartment 134, and an additional opening 131 for electrical and clean dry air (CDA) lines.

The first compartment 132 may be defined by the first main side 104 (FIG. 1), the second main side 106, the top plate 116, the first side 112, the second side 114, and the divider wall 115. The first compartment 132 may be in communication with the exhaust assembly 118, which may include an exhaust duct 135 extending from the top plate 116 of the enclosure 102. Exhaust (e.g., air and any gas leaks) may be removed from the first compartment 132 via the exhaust duct 135, as shown by arrow 136. A first flow control device 137 is operable to control air flow between the first compartment 132 and the exhaust assembly 118.

The second compartment 134 may be defined by the first main side 104, the second main side 106, the first side 112, the second side 114, and a bottom plate 138 at the second end 110 of the enclosure 102. The second compartment 134 may also be in communication with the exhaust assembly 118, wherein air and any gas leaks may be removed from the second compartment 134 via the exhaust duct 135. To allow communication of the air to the exhaust assembly 118, a conduit or duct 140 may connect the second compartment 134 and the exhaust duct 135. That is, the duct 140 may include a first end 143 extending into an interior of the exhaust duct 135 and a second end 141 extending to the divider wall 115. In various embodiments, the second end 141 of the duct 140 may abut, or extend through, an opening 142 of the divider wall 115 to provide a pathway for air within the second compartment 134 to be delivered to the exhaust duct 135. More specifically, the second end 143 of the duct 140 may abut an upper surface 190 of the divider wall 115, forming a seal around the opening 142, or may extend through the opening 142 for direct connection with a second flow control device 144, which is operable to control air flow between the second compartment 134 and the duct 140.

Although non-limiting, the duct 140 may be a hollow tube or cylinder open at the first end 143 and the second end 141. A seal may be formed between the duct 140 and the divider wall 115 to isolate the first and second compartments 132, 134 from one another. The duct 140 allows the enclosure 102 to be more compact, as the duct 140 passes through the first compartment 132 instead of, for example, along an exterior of the enclosure 102.

In some embodiments, the first and second flow control device 137, 144 may each be a “blast gate” shutoff/isolation device operable to selectively control air flow through the exhaust assembly 118. That is, the first and second flow control devices 137, 144 may both be open, both be closed, or only one of the first and second flow control devices 137, 144 may be open while the other is closed. The first and second flow control devices 137, 144 may operate with a pump (not shown) to draw the air and/or gas towards the exhaust assembly 118 for removal. In some embodiments, the opening percentage of the first and/or second flow control devices 137, 144 is adjustable. For example, in the event a gas leak is detected within the first compartment 132, a facility gas line (not shown) may be shutoff and the first compartment 132 put under maintenance to address the leak. Then the first flow control device 137 may be closed while the second flow control device 144 is partially opened and the exhaust through the exhaust duct 135 is constant.

As further shown in FIG. 2, the first compartment 132 may house a variety of gas flow components, such as a first gas pallet assembly 145 including a first plurality of gas sticks 146 and a water vapor source 148, the first gas pallet assembly 145 further having one or more valves, filters, mass flow controllers (MFCs) and/or other components to flow one or more gases from the first plurality of gas sticks 146 into a first substrate processing chamber 160A. The one or more gases may be combined and delivered as a process gas. In some embodiments, the gas pallet assembly 145 may include one or more pneumatic valves operable to receive a flow of CDA from one or more manifolds 147. Although non-limiting, each manifold 147 may be an electronic vacuum (EV) manifold including an electric contactor and one or more electrical valves operable to control the flow of the CDA delivered into one or more supply lines. The pneumatic valves of the first gas pallet assembly 145 may open/close based on the CDA pressure from the supply lines, thereby controlling gas flow to the first substrate processing chamber 160A. In some embodiments, the first gas pallet assembly 145 may further include various safety devices/sensors ensuring the safe operation of the gas panel assembly 100 (e.g., differential pressure switch, leak sensor, pressure switches etc.).

The first compartment 132 may further include a plurality of electrical components 152 operable with the first gas pallet assembly 145. Although not exhaustive, the plurality of electrical components 152 may include the EV manifolds 147, one or more a power sources (e.g., DC power strip) for distributing electrical power to the EV manifolds 147, and one or more differential pressure switches 149. In some embodiments, the plurality of electrical components 152 may further include an electronic receiver and a transmitter (not shown) for providing communication to control gas flow from the first gas pallet assembly 145 to the first substrate processing chamber 160A by, for example, opening/closing one or more the pneumatic valves associated with each gas stick one 46.

The enclosure 102 may further include the first plurality of openings 122 along the first side 112 and a second plurality of openings 123 along the second side 114 to receive ambient air into the first compartment 132 from an exterior of the enclosure 102. It will be appreciated that the number and placement of the first and second plurality of openings 122, 123 is shown for illustrative purposes only, and may vary in alternative embodiments.

Similarly, the second compartment 134 may house a variety of gas flow components, such as a second gas pallet assembly 155 including a second plurality of gas sticks 156, the second gas pallet assembly 155 having one or more valves, filters, MFCs and/or other components to flow one or more gases into a second substrate processing chamber 160B. The one or more gases may be combined and delivered as a process gas. In some embodiments, the second gas pallet assembly 155 may include one or more pneumatic valves operable to receive a flow of CDA from one or more manifolds 157. Each manifold 157 may be an EV manifold including an electric contactor and one or more electrical valves operable to control the flow of the CDA delivered into one or more supply lines. The pneumatic valves of the second gas pallet assembly 155 may open/close based on the CDA pressure from the supply lines, thereby controlling gas flow to the second substrate processing chamber 160B.

The second compartment 134 may further include a plurality of electrical components operable with the second gas pallet assembly 155. Although not exhaustive, the plurality of electrical components may include the EV manifolds 157, one or more a power sources for distributing electrical power to the EV manifolds 157, and one or more differential pressure switches 161. In some embodiments, the plurality of electrical components may further include an electronic receiver and a transmitter (not shown) for providing communication to control gas flow from the second gas pallet assembly 155 to the second substrate processing chamber 160B by, for example, opening/closing one or more the pneumatic valves associated with each gas stick 156. In various embodiments, the second gas pallet assembly 155 and the first gas pallet assembly 145 may be independently operated to supply the desired gases to the respective first and second substrate processing chambers 160A, 160B.

The enclosure 102 may further include the first plurality of openings 122 along the first side 112 and the second plurality of openings 123 along the second side 114 to receive ambient air into the second compartment 134 from an exterior of the enclosure 102. In some embodiments, a third plurality of openings 139 may extend through the bottom plate 138 of the enclosure 102 to further increase intake of ambient air into the second compartment 134.

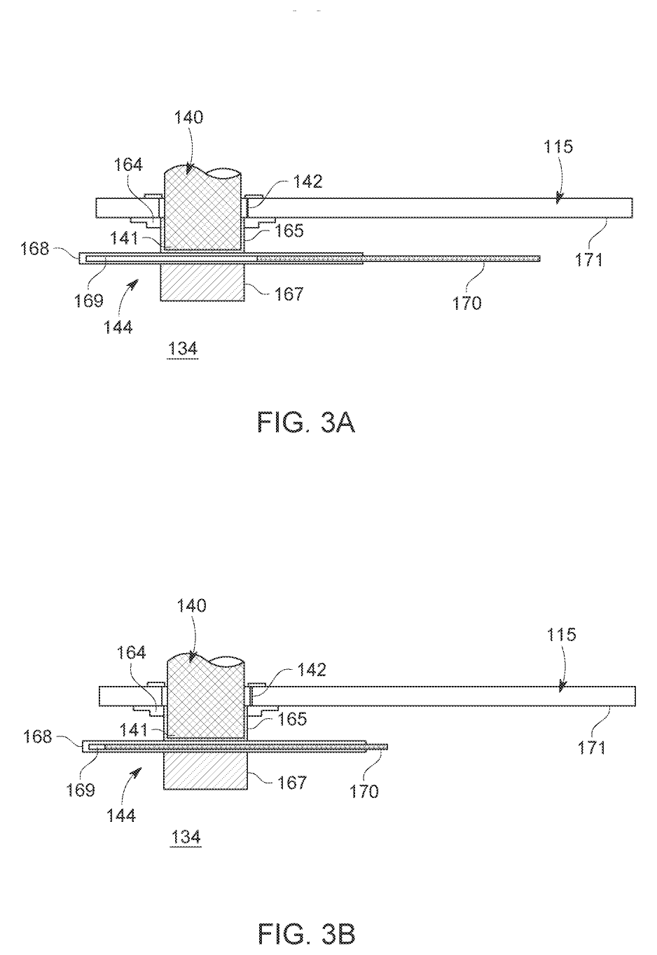

FIGS. 3A-3B demonstrate operation of the second flow control device 144 in greater detail. As shown, the second flow control device 144 may include an upper section 165 extending through a collar 164, wherein the collar 164 is coupled to an underside 171 the divider wall 115. The upper section 165 may be further coupled to a channel plate 168. In some embodiments, a flange of the collar 164 may extend along an upper surface of the divider wall 115. A lower section 167 of the second flow control device 144 may be coupled to, and extend below, the channel plate 168. The second end 141 of the duct 140 may pass through the opening 142 of the divider wall 115, and extend within an interior of the upper section 165. The channel plate 168 may include a slot or channel 169 through which a gate slider 170 may move, e.g., horizontally, to open and close the second flow control device 144. The upper section 165 and the lower section 167 of the second flow control device 144 may be hollow to permit air from the second compartment 134 to enter the duct 140.

In the configuration shown in FIG. 3A, the second flow control device 144 is open when the gate slider 170 is not present between the upper section 165 and the lower section 167. Air from the second compartment 134 is therefore permitted to flow through the lower section 167 and the channel plate 168, and then into the duct 140 via the upper section 165. In the configuration shown in FIG. 3B, the second flow control device 144 is closed, as the gate slider 170 has been moved laterally within the channel 169 until the gate slider 170 is positioned between the upper and lower sections 165, 167. The air from the second compartment 134 is therefore prevented from entering the duct 140. As stated above, in some embodiments, the gate slider 170 may be moved to a partially open position to still permit some air to reach the duct 140. In some embodiments, the second flow control device 144 is a blast gate or a valve.

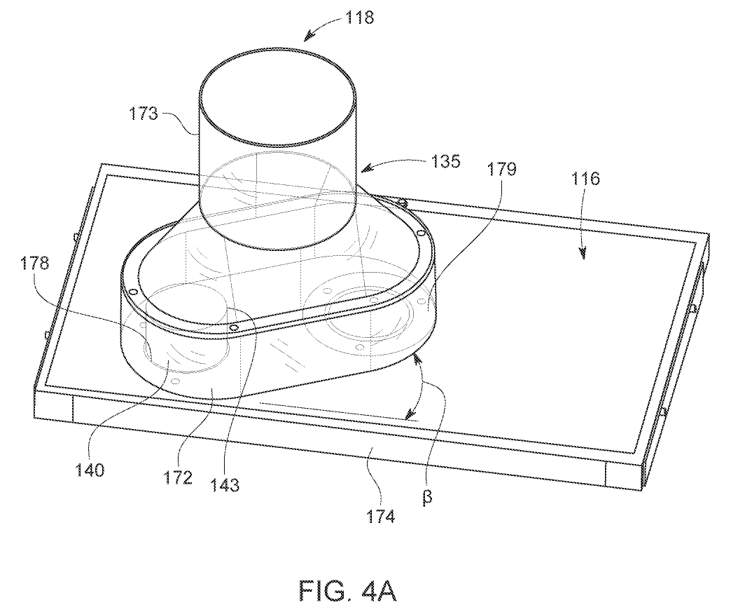

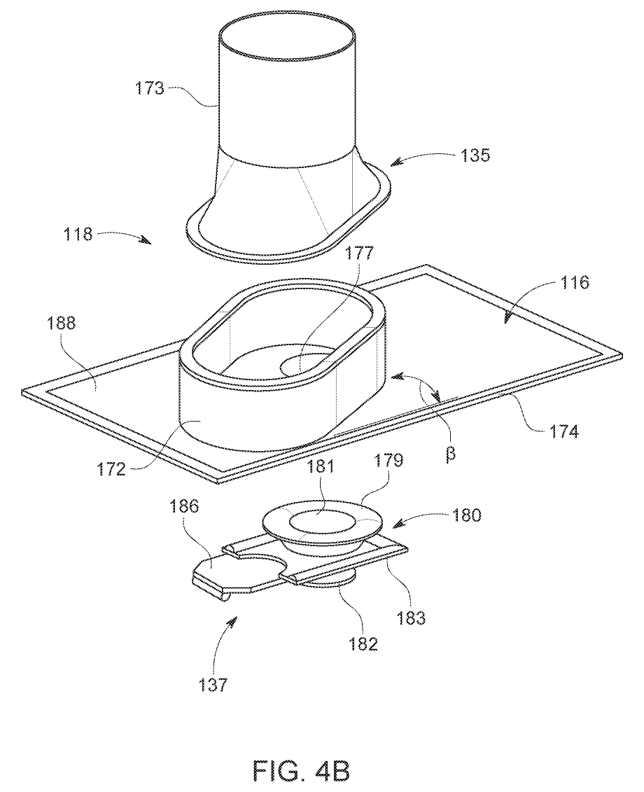

FIGS. 4A-4B depict the first flow control device 137 and the exhaust assembly 118 in greater detail. As shown, the exhaust duct 135 of the exhaust assembly 118 may include a lower portion 172 coupled to, or integrally formed with, an upper portion 173, wherein the lower portion 172 is secured (e.g., welded) to the top plate 116. In some embodiments, the lower portion 172 may be arranged at a non-zero angle ‘β’relative to a plane defined by a side 174 of the top plate 116 to allow a more compact arrangement of the first flow control device 137 and the duct 140.

The top plate 116 may include a first opening 177 (FIG. 4B) operable to receive the first flow control device 137, and a second opening 178 (FIG. 4A) operable to receive the first end 143 of the duct 140. Air from the second compartment 134 may enter an interior of the exhaust duct 135 when the second flow control device 144 is open. In some embodiments, the first flow control device 137 may include a collar 179 extending through the first opening 177.

As better shown in FIG. 4B, the first flow control device 137 may further include an upper section 181 connected to a channel plate 183, the upper section 181 coupled to the top plate 116 by the collar 179. More specifically, the upper section 181 may extend through the first opening 177 of the top plate 116, while a lower section 182 extends beneath the channel plate 183. The collar 179 may wrap around the upper section 181, wherein a flange of the collar 179 may extend along an upper surface of the top plate 116. The channel plate 183 may further include a slot or channel through which a gate slider 186 may move to open and close the first flow control device 137. The lower section 182 may be hollow and open to an interior of the first compartment 132 to permit air from the first compartment 132 to enter the exhaust duct 135. In some embodiments, the first flow control device 137 is a blast gate.

For the sake of convenience and clarity, terms such as "top," "bottom," "upper," "lower," "vertical," "horizontal," "lateral," and "longitudinal" will be used herein to describe the relative placement and orientation of components and their constituent parts as appearing in the figures. The terminology will include the words specifically mentioned, derivatives thereof, and words of similar import.

As used herein, an element or operation recited in the singular and proceeded with the word "a" or "an" is to be understood as including plural elements or operations, until such exclusion is explicitly recited. Furthermore, references to "one implementation" of the present disclosure are not intended as limiting. Additional implementations may also incorporate the recited features.

Furthermore, the terms “substantial” or “substantially,” as well as the terms “approximate” or “approximately,” can be used interchangeably in some implementations, and can be described using any relative measures acceptable by one of ordinary skill in the art. For example, these terms can serve as a comparison to a reference parameter, to indicate a deviation capable of providing the intended function. Although non-limiting, the deviation from the reference parameter can be, for example, in an amount of less than 1%, less than 3%, less than 5%, less than 10%, less than 15%, less than 20%, and so on.

The present disclosure is not to be limited in scope by the specific implementations described herein. Indeed, other various implementations of and modifications to the present disclosure, in addition to those described herein, will be apparent to those of ordinary skill in the art from the foregoing description and accompanying drawings. Thus, such other implementations and modifications are intended to fall within the scope of the present disclosure. Furthermore, the present disclosure has been described herein in the context of a particular implementation in a particular environment for a particular purpose. Those of ordinary skill in the art will recognize the usefulness is not limited thereto and the present disclosure may be beneficially implemented in any number of environments for any number of purposes. Thus, the claims set forth below are to be construed in view of the full breadth and spirit of the present disclosure as described herein.

What is claimed is:

1. A gas panel assembly, comprising:
an enclosure defining a first compartment and a second compartment separated from one another by a divider wall;
a first gas pallet assembly within the first compartment, wherein the first gas pallet assembly is operable to provide a first gas to a first substrate processing chamber;
a second gas pallet assembly within the second compartment, wherein the second gas pallet assembly is operable to provide a second gas to a second substrate processing chamber;
a first flow control device between the first compartment and an exhaust, the first flow control device operable to control air flow between the first compartment and the exhaust; and
a duct connecting the second compartment and the exhaust, wherein a second flow control device is operable to control air flow between the second compartment and the duct.

2. The gas panel assembly of claim 1, wherein the divider wall comprises an opening, and wherein the duct extends through the opening.

3. The gas panel assembly of claim 1, wherein the enclosure further comprises a top plate, and wherein the duct extends through a first opening of the top plate.

4. The gas panel assembly of claim 3, wherein the top plate further comprises a second opening, and wherein the first flow control device controls air flow through the second opening.

5. The gas panel assembly of claim 4, wherein the exhaust comprises an exhaust duct coupled to the top plate.

6. The gas panel assembly of claim 5, wherein a first end of the duct extends into an interior of the exhaust duct, and wherein a second end of the duct extends into the second compartment.

7. The gas panel assembly of claim 1, wherein the enclosure further comprises a side plate and a bottom plate, wherein a plurality of openings are formed through at least one of the side plate and the bottom plate.

8. The gas panel assembly of claim 1, wherein the duct passes through the first compartment.

9. The gas panel assembly of claim 1, wherein the first and second flow control devices are blast gates.

10. A gas panel assembly of a semiconductor processing system, the gas panel assembly comprising:
an enclosure comprising a top plate opposite a bottom plate, a first side plate opposite a second side plate, and a divider wall extending between the first and second side plates, wherein the divider wall separates a first compartment from a second compartment;
a first gas pallet assembly and a first plurality of electrical components within the first compartment, wherein the first plurality of electrical components is operable to control gas flow from the first gas pallet assembly to a first substrate processing chamber;
a second gas pallet assembly and a second plurality of electrical components within the second compartment, wherein the second plurality of electrical components is operable to control gas flow from the second gas pallet assembly to a second substrate processing chamber;
a first flow control device coupled to the top plate, the first flow control device operable to control air flow between the first compartment and an exhaust; and
a duct connecting the second compartment and the exhaust, wherein a second flow control device coupled to the duct is operable to control air flow between the second compartment and the duct.

11. The gas panel assembly of claim 10, wherein the duct comprises a first end extending through a first opening of the top plate and a second end extending through an opening of the divider wall.

12. The gas panel assembly of claim 11, wherein the top plate further comprises a second opening, and wherein the first flow control device controls air flow through the second opening.

13. The gas panel assembly of claim 11, wherein the exhaust comprises an exhaust duct coupled to the top plate, and wherein the first end of the duct extends into the exhaust duct.

14. The gas panel assembly of claim 10, further comprising a plurality of openings formed through at least one of the following: the first side plate, the second side plate, and the bottom plate.

15. The gas panel assembly of claim 10, wherein the duct passes through the first compartment.

16. An apparatus for delivering gases to one or more substrate processing chambers, the apparatus comprising:
an enclosure comprising a top plate opposite a bottom plate, a first side plate opposite a second side plate, and a divider wall extending between the first and second side plates, wherein the divider wall separates a first compartment from a second compartment;
a first gas pallet assembly and a first plurality of electrical components within the first compartment, wherein the first plurality of electrical components is operable to control gas flow from the first gas pallet assembly to a first substrate processing chamber;
a second gas pallet assembly and a second plurality of electrical components within the second compartment, wherein the second plurality of electrical components is operable to control gas flow from the second gas pallet assembly to a second substrate processing chamber;
a first flow control device coupled to the top plate, the first flow control device operable to control air flow between the first compartment and an exhaust; and
a duct extending between the second compartment and the exhaust, wherein a second flow control device coupled to the divider wall is operable to control air flow of between the second compartment and the duct, and wherein the duct extends through an interior of the first compartment.

17. The apparatus of claim 16, wherein the top plate comprises:
a first opening receiving a first end of the duct; and
a second opening adjacent the first opening, wherein the first flow control device controls air flow through the second opening.

18. The apparatus of claim 16, wherein the exhaust comprises an exhaust duct connected to the top plate, wherein a first end of the duct extends into the exhaust duct, and wherein a second end of the duct extends through an opening of the divider wall.

19. The apparatus of claim 16, further comprising a plurality of openings formed through at least one of the following: the first side plate, the second side plate, and the bottom plate.

20. The apparatus of claim 16, wherein the first and second flow control devices are blast gates.
